(19) United States
(12) Patent Application Publication
(10) Pub. No.: US 2023/0170274 A1
(43) Pub. Date: Jun. 1, 2023

(54) PACKAGING STRUCTURE AND MANUFACTURING METHOD THEREOF

(71) Applicant: JCET MANAGEMENT CO., LTD., Shanghai City (CN)

(72) Inventor: CHENG YANG, Wuxi City (CN)

(21) Appl. No.: 18/073,045

(22) Filed: Dec. 1, 2022

(30) Foreign Application Priority Data
Dec. 1, 2021 (CN) 202111452217.2

(51) Int. Cl. H01L 23/367; H01L 23/13; H01L 25/065; H01L 23/498; H01L 23/00; H01L 21/48; H01L 25/00

(52) U.S. Cl. CPC H01L 23/3675; H01L 23/13; H01L 25/0657; H01L 23/49816; H01L 23/49833; H01L 24/16; H01L 24/32; H01L 24/73; H01L 21/4882; H01L 25/50; H01L 2924/15151; H01L 2924/152; H01L 2225/06517; H01L 2225/06513; H01L 2225/06524; H01L 2225/06589; H01L 2225/06562; H01L 2225/06568; H01L 2224/73253; H01L 2224/16145; H01L 2224/16227; H01L 2224/16238; H01L 2224/32225; H01L 2224/32245

(57) ABSTRACT

The present invention provides a packaging structure and a manufacturing method thereof. The packaging structure includes a first chip, a second chip, a first heat conductor and a second heat conductor, wherein the first chip includes a first connecting surface and a first heat-conducting surface; the second chip is disposed on a side of the first connecting surface and electrically connected to the first chip, and a side of the second chip distal from the first chip includes a second heat-conducting surface; the first heat conductor is connected to the first heat-conducting surface; and the second heat conductor is connected to the second heat-conducting surface. A first heat-conducting channel is formed between the first heat-conducting surface and the first heat conductor, a second heat-conducting channel is formed between the second heat-conducting surface and the second heat conductor. Thus, the heat dissipation efficiency of the packaging structure can be significantly improved.

### TECHNICAL FIELD

The present invention belongs to the field of semiconductor packaging technologies, and particularly relates to a packaging structure and a manufacturing method thereof.

### BACKGROUND

The chip-on-wafer-on-substrate (CoWoS)-based 2.5D packaging technology is to package a chip onto a silicon interposer, to interconnect them using high-density wiring on the silicon interposer, and to further connect them to a package substrate. CoWoS mainly focuses on a high-performance computing (HPC) market, for example, high-end products with high-bandwidth memory (HBM) memories. At present, the silicon interposer may also be replaced with an organic interposer with a redistribution layer (RDL).

In addition, the embedded multi-die interconnect bridge (EMIB)-based advanced packaging technology is similar to 2.5D packaging of a silicon interposer and provides local high-density interconnection by burying a silicon bridge for connection with dies into a package substrate. The EMIB technology can provide high-density interconnection for packaging between a discrete graphics card and a high-bandwidth memory chip.

When the above-mentioned advanced packaging technology is applied to packaging of an active device for a high-bandwidth memory, 1) the presence of the interposer and the silicon bridge limits the I/O speed and leads to higher power consumption; 2) a through Si vias (TSV) process in the 2.5D packaging technology results in a high cost; redistribution of the RDL is limited a lot by the wiring density; the silicon bridge process and an assembling process are complex; and 3) 3D packaging on the active device by the TSV is costly in a packaging process and has a heat dissipation problem.

### SUMMARY

A problem solved by the present invention is how to improve the heat dissipation capability between 3D packaged chips.

In order to solve the above problem, a technical solution of the present invention provides a packaging structure. The packaging structure includes: a first chip, including a first connecting surface and a first heat-conducting surface that face away from each other; a second chip, disposed on a side of the first connecting surface and electrically connected to the first chip, and a side of the second chip distal from the first chip including a second heat-conducting surface; and a first heat conductor and a second heat conductor, the first heat conductor being connected to the first heat-conducting surface, and the second heat conductor being connected to the second heat-conducting surface.

As an optional technical solution, the packaging structure further includes a first substrate having a cavity in which the first chip is placed. A gap between the first chip and the cavity is filled with a bonding material.

As an optional technical solution, the cavity is a through hole running through the first substrate, and the first heat-conducting surface is exposed from the through hole.

As an optional technical solution, the first heat conductor is disposed on a side of the first substrate distal from the second chip and connected to the first heat-conducting surface exposed from the through hole.

As an optional technical solution, the packaging structure further includes a second substrate disposed on a side of the first substrate distal from the second chip and electrically connected to the first substrate. The first heat conductor includes a heat-conducting back plate and an extension extending from the heat-conducting back plate. The second substrate is provided with a notch for the extension, the extension is inserted into the notch to be connected to the first heat-conducting surface, and the second substrate is sandwiched between the first substrate and the heat-conducting back plate.

As an optional technical solution, the cavity is a blind hole not running through the first substrate, and the first heat-conducting surface is connected to a bottom of the blind hole.

As an optional technical solution, the first heat conductor is disposed on an outer side of the bottom of the blind hole and connected to the bottom of the blind hole.

As an optional technical solution, a size of the second chip is larger than a size of the first chip, and a metal bump protrudes from a second connecting surface of the second chip facing the first substrate and is electrically connected to a corresponding first bonding pad on the first substrate.

As an optional technical solution, the packaging structure further includes an interposer, and the interposer is electrically connected to the first chip and the first substrate.

As an optional technical solution, a part of a heat-conducting area of the second heat conductor covers a side of the interposer distal from the first substrate.

As an optional technical solution, a side of the second chip facing the first chip includes an interconnecting structural layer, and the interconnecting structural layer is electrically connected to the first chip and the first substrate.

As an optional technical solution, the first chip further includes a first connecting surface facing away from the first heat-conducting surface, the first connecting surface protrudes from or is flush with a third connecting surface of the first substrate, and the first connecting surface faces the third connecting surface.

The present invention further provides a manufacturing method of a packaging structure. The manufacturing method includes: providing a first chip and a second chip that are electrically connected, the first chip including a first heat-conducting surface distal from the second chip, and the second chip including a second heat-conducting surface distal from the first chip; connecting a first heat conductor to the first heat-conducting surface; and connecting a second heat conductor to the second heat-conducting surface.

As an optional technical solution, prior to connecting the first heat conductor to the first heat-conducting surface, the manufacturing method further includes:

providing a first substrate having a cavity, the cavity being a through hole; placing the first chip into the through hole, and enabling the first heat-conducting surface to be exposed from the through hole; and filling a gap between the first chip and the cavity with a bonding material, and fixing the first chip to the first substrate.

As an optional technical solution, connecting the first heat conductor to the first heat-conducting surface further includes:

providing a first substrate having a cavity, the cavity being a blind hole, and the first heat conductor being disposed at a bottom of the blind hole; and placing the first chip into the blind hole, and connecting the first heat conductor to the first heat-conducting surface.

Compared with the prior art, the present invention provides the packaging structure and the manufacturing method thereof. The packaging structure includes the first chip and the second chip that are electrically connected. The first chip includes the first heat-conducting surface distal from the second chip, and the second chip includes the second heat-conducting surface distal from the first chip. The first heat conductor and the second heat conductor are disposed on the first heat-conducting surface and the second heat-conducting surface which are away from each other to lead out heat produced by operations of the first chip and the second chip. That is, a first heat-conducting channel is formed between the first heat-conducting surface of the first chip and the first heat conductor, and a second heat-conducting channel is formed between the second heat-conducting surface of the second chip and the second heat conductor. The first heat-conducting channel and the second heat-conducting channel accelerate heat conduction, and thus, the heat dissipation efficiency of the packaging structure can be significantly improved.

The present invention is described in detail below with reference to the accompanying drawings and specific embodiments, but is not intended to limit the present invention.

### BRIEF DESCRIPTION OF THE DRAWINGS

For clearer descriptions of the technical solutions in the embodiments of the present invention or in the prior art, the following briefly introduces the accompanying drawings required for describing the specific embodiments or the prior art. Apparently, the accompanying drawings in the following description show merely some embodiments of the present invention, and a person of ordinary skill in the art may still derive other drawings from these accompanying drawings without creative efforts.

FIG. 1 is a schematic sectional diagram of a packaging structure according to a first embodiment of the present invention;

FIG. 2 is a schematic sectional diagram of a manufacturing process of the packaging structure in FIG. 1;

FIG. 3 is a schematic sectional diagram of a packaging structure according to a second embodiment of the present invention;

FIG. 4 is a schematic sectional diagram of a packaging structure according to a third embodiment of the present invention;

FIG. 5 is a schematic sectional diagram of a packaging structure according to a fourth embodiment of the present invention;

FIG. 6 is a schematic sectional diagram of a packaging structure according to a fifth embodiment of the present invention;

FIG. 7 is a schematic sectional diagram of a packaging structure according to a sixth embodiment of the present invention;

FIG. 8 is a schematic sectional diagram of a packaging structure according to a seventh embodiment of the present invention; and

FIG. 9 is a flow chart of a manufacturing method of a packaging structure according to the present invention.

### DETAILED DESCRIPTION

In order to make the objectives, technical solutions and advantages of the present invention clearer, the present invention will be further described in detail below with reference to the embodiments and the accompanying drawings. It should be understood that the specific embodiments described herein are only used to explain the present invention, but not to limit the present invention.

In the descriptions of the present invention, it should be understood that directional or positional relationships shown by the terms such as “center”, “upper”, “lower”, “left”, “right”, “vertical”, “horizontal”, “inner”, and “outer” are directional or positional relationships shown as in the drawings, which only intend to facilitate description of the present invention and simplify the description, but do not indicate or imply that the apparatuses or components must have specific directions, or be constructed or operated in the specific directions, and are not limitative of the present invention.

One of the objects of the present invention is to provide a packaging structure, including a first chip, a second chip, a first heat conductor and a second heat conductor. The first chip includes a first connecting surface and a first heat-conducting surface that face away from each other. The second chip is disposed on a side of the first connecting surface and electrically connected to the first chip; and a side of the second chip distal from the first chip includes a second heat-conducting surface. The first heat conductor is disposed on the first heat-conducting surface, and the second heat conductor is disposed on the second heat-conducting surface. Therefore, the heat conductivity of the packaging structure is improved.

In this embodiment, the first chip and the second chip are respectively high-power-consumption elements such as an HBM, a hybrid memory cube (HMC), a CPU and a GPU, which have obvious requirements for heat conduction in the working process. Because the first chip and the second chip are vertically interconnected in the packaging structure according to the present invention, and the first heat conductor and the second heat conductor are respectively disposed on the first heat-conducting surface and the second heat-conducting surface which are away from each other to lead out heat produced by the operations of the first chip and the second chip. That is, a first heat-conducting channel is formed between the first heat-conducting surface of the first chip and the first heat conductor, and a second heat-conducting channel is formed between the second heat-conducting surface of the second chip and the second heat conductor. The first heat-conducting channel and the second heat-conducting channel accelerate heat conduction, and thus, the heat dissipation efficiency of the packaging structure can be significantly improved.

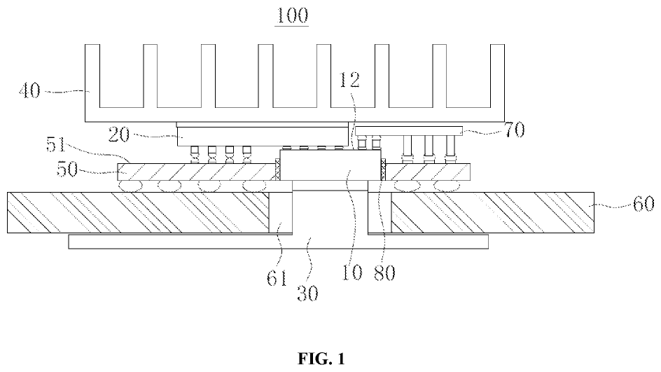

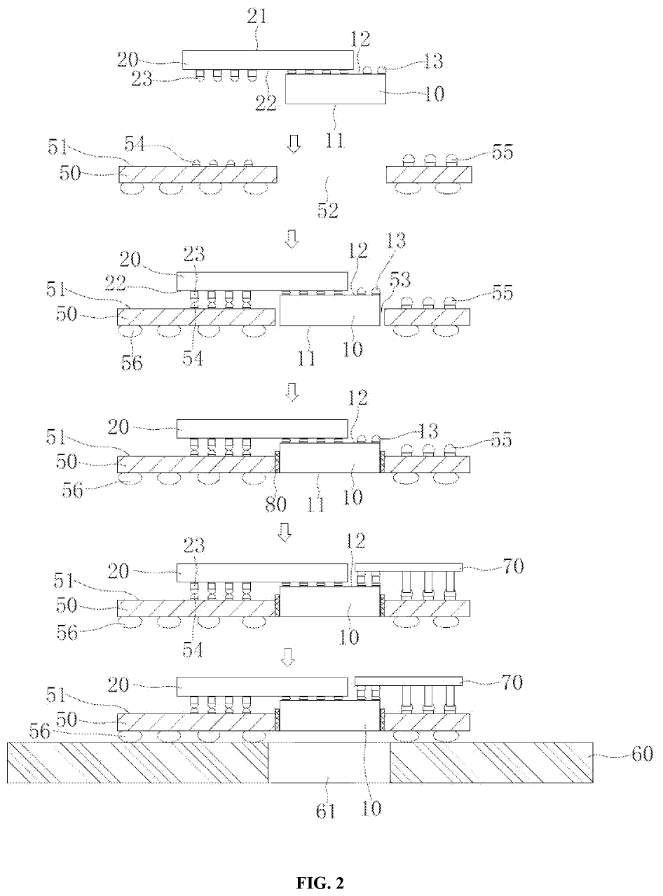

As shown in FIGS. 1 and 2, a packaging structure 100 is provided according to a first embodiment of the present invention, and includes a first chip 10, a second chip 20, a first heat conductor 30 and a second heat conductor 40. The second chip 20 is disposed above and electrically connected to the first chip 10. The first chip 10 includes a first heat-conducting surface 11 distal from the second chip 20, and the second chip 20 includes a second heat-conducting surface 21 distal from the first chip 10. The first heat conductor 30 is connected to the first heat-conducting surface 11, and the second heat conductor 40 is connected to the second heat-conducting surface 21.

In a preferred embodiment, the first heat conductor 30 is for example a heat-conducting back plate, and the heat-conducting back plate and the first heat-conducting surface 11 are connected by a heat-conducting glue. The second heat conductor 40 is for example a heat-conducting fin, and the heat-conducting fin and the second heat-conducting surface 21 are also connected by the heat-conducting glue. The heat-conducting back plate and the heat-conducting fin are preferably made from heat-conducting metal materials.

As shown in FIGS. 1 and 2, the packaging structure 100 further includes a first substrate 50 having a cavity 52 in which the first chip 10 is placed. A gap 53 between the first chip 10 and the cavity 52 is filled with a bonding material 80. The bonding material 80 is, for example, an adhesive material by which the first chip 10 is fixed in the cavity 52 of the first substrate 50.

In this embodiment, the cavity 52 is a through hole running through the first substrate 50. The first heat-conducting surface 11 of the first chip 10 is exposed from the through hole and connected to the first heat conductor 30.

It can be known from FIG. 2 that the first chip 10 and the second chip 20 are pre-bonded to form a separate chip unit component, and the first chip 10 is fixed in the cavity 52 of the first substrate 50 by the bonding material 80 after the chip unit component is aligned with the first substrate 50 having the cavity 52.

It should be noted that in this embodiment, the first chip 10 is thicker than the first substrate 50, such that a first connecting surface 12 of the first chip 10 protrudes from a third connecting surface 51 of the first substrate 50. The first connecting surface 12 and the first heat-conducting surface 11 face away from each other, and the third connecting surface 51 and a second connecting surface 22 are opposite to each other.

In other embodiments of the present invention, the first connecting surface 12 of the first chip 10 and the third connecting surface 51 of the first substrate 50 may be flush with each other.

Continuously referring to FIGS. 1 and 2, the size of the second chip 20 is larger than that of the first chip 10. A part of the second chip 20 protrudes from an edge of the first chip 10. Metal bumps 23 protrude from the second connecting surface 22 of the second chip 20 facing the first substrate 50 and are electrically connected to corresponding first bonding pads 54 on the first substrate 50. The second connecting surface 22 and the first heat-conducting surface 21 face away from each other. The electrical connection mode includes but is not limited to tin-gold bonding.

In addition, the packaging structure 100 further includes an interposer 70, and the interposer 70 is disposed on a side of the first connecting surface 12 of the first chip 10 and meanwhile electrically connected to the metal bumps 13 on the first connecting surface 12 of the first chip 10 and second bonding pads 55 on the third connecting surface 51 of the first substrate 50. The interposer 70 is configured to power up the first chip 10, read part of electrical signals output by the first chip 10, transmit the read electrical signals to the first substrate 50, and output the electrical signals by the first substrate 50.

Continuously referring to FIGS. 1 and 2, the packaging structure 100 further includes a second substrate 60. The second substrate 60 is for example a PCB. The PCB includes fourth bonding pads (not shown). The fourth bonding pads are electrically connected to third bonding pads 56 on the back side of the first substrate 50, such that the second substrate 60 and the first substrate 50 are electrically connected to each other.

Furthermore, the first heat conductor 30 includes a heat-conducting back plate and an extension extending from the heat-conducting back plate. A notch 61 is formed in the second substrate 60 and corresponds to the extension, and the extension is inserted into the notch 61 and connected to the first heat-conducting surface 11 exposed outside the cavity 52 of the first substrate 50.

In addition, the heat-conducting back plate is located below the second substrate 60 and combined with the second substrate 60, such that heat may be exported by a material with a high heat conductivity in the second substrate 60, i.e., part of the heat of the first heat conductor 30 may be exported by the second substrate 60, which further improves the heat dissipation efficiency.

In the packaging structure 100 according to the present invention, a heat-conducting channel is formed on each of the heat-conducting surfaces, facing away from each other, of the first chip 10 and the second chip 20 that are vertically interconnected. Therefore, the heat dissipation efficiency of the packaging structure 100 can be significantly improved.

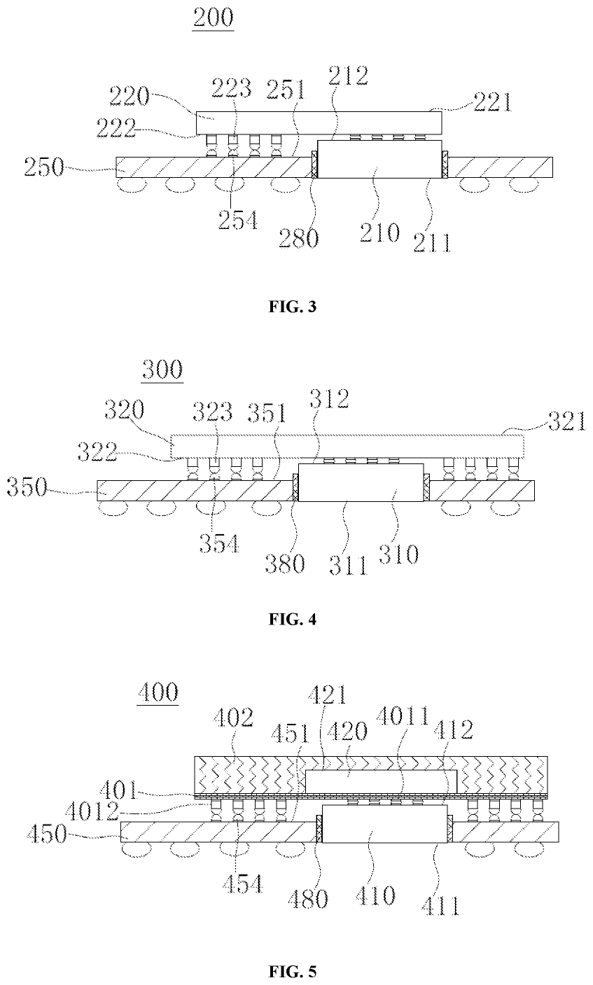

As shown in FIG. 3, a packaging structure 200 is provided according to a second embodiment of the present invention, and differs from the packaging structure 100 in that one side of a second chip 220 in the packaging structure 200 is electrically connected to a first substrate 250.

In addition, in order to simplify the diagram, illustrations of the first heat conductor, the second heat conductor and the second substrate are omitted in the packaging structure 200 shown in FIG. 2. A reference may be made to FIG. 1 for the first heat conductor, the second heat conductor and the second substrate, which are not repeated herein.

In this embodiment, after a chip unit component formed by pre-bonding a first chip 210 and the second chip 220 is aligned with the first substrate 250, the first chip 210 is fixed in a cavity, for example, a through hole, of the first substrate 250 by a bonding material 280. A first connecting surface 212 of the first chip 210 protrudes from, for example, a third connecting surface 251 of the first substrate 250. A first heat-conducting surface 211 of the first chip 210 is connected to a first heat conductor, and a second heat-conducting surface 221 of the second chip 220 is connected to a second heat conductor.

The size of the second chip 220 is larger than the size of the first chip 210. One side of the second chip 220 protrudes from an edge of the first chip 210. A part of the second connecting surface 222 of the second chip 220 faces a part of the third connecting surface 251 of the first substrate 250. Metal bumps 223 on the second connecting surface 222 are electrically connected to first bonding pads 254 on the third connecting surface 251. The metal bumps 223 and the first bonding pads 254 are electrically connected by means of, but not limited to, tin-gold bonding.

In this embodiment, the second chip 220 is electrically connected to the first chip 210 and the first substrate 250 that are below the second chip 220. For example, the first chip 210 is an HBM and the second chip 220 is a CPU. The HBM may be powered up by the CPU or by the redistributed first substrate 250 after redistribution is performed on the first substrate 250.

As shown in FIG. 4, a packaging structure 300 is further provided according to a third embodiment of the present invention, and differs from the packaging structure 100 in that two sides of a second chip 320 in the packaging structure 300 are electrically connected to a first substrate 350.

In addition, in order to simplify the diagram, illustrations of the first heat conductor, the second heat conductor and the second substrate are omitted in the packaging structure 300 shown in FIG. 4. A reference may be made to FIG. 1 for the first heat conductor, the second heat conductor and the second substrate, which are not repeated herein.

In this embodiment, after a chip unit component formed by pre-bonding a first chip 310 and the second chip 320 is aligned with the first substrate 350, the first chip 310 is fixed in a cavity, for example, a through hole, of the first substrate 350 by a bonding material 380. A first connecting surface 312 of the first chip 310 protrudes from, for example, a third connecting surface 351 of the first substrate 350. A first heat-conducting surface 311 of the first chip 310 is connected to a first heat conductor, and a second heat-conducting surface 321 of the second chip 320 is connected to a second heat conductor.

The size of the second chip 320 is larger than that of the first chip 310. Two sides of the second chip 320 protrude from edges on two sides of the first chip 310, respectively. A part of the second connecting surface 322 of the second chip 320 faces a part of the third connecting surface 351 of the first substrate 350. Metal bumps 323 on the second connecting surface 322 are electrically connected to corresponding first bonding pads 354 on the third connecting surface 351.

The metal bumps 323 and the first bonding pads 354 are electrically connected by means of, but not limited to, tin-gold bonding.

In this embodiment, the second chip 320 is electrically connected to the first chip 310 and the first substrate 350 that are below the second chip 320. For example, the first chip 310 is an HBM and the second chip 320 is a CPU.

As shown in FIG. 5, a packaging structure 400 is further provided according to a fourth embodiment of the present invention, and differs from the packaging structure 100 in that a second chip 420 in the packaging structure 400 is electrically connected to a first substrate 450 and a first chip 410 by a redistribution layer 401.

In addition, in order to simplify the diagram, illustrations of the first heat conductor, the second heat conductor and the second substrate are omitted in the packaging structure 400 shown in FIG. 5. A reference may be made to FIG. 1 for the first heat conductor, the second heat conductor and the second substrate, which are not repeated herein.

In this embodiment, the second chip 420 includes a plastic package layer 402 around the second chip 420; an active layer of the second chip 420 is exposed from the plastic package layer 402 and is approximately flush with the plastic package layer 402; the redistribution layer 401 is formed on one side of the plastic package layer 402, and is electrically connected to the active layer; and thus, a second chip component is formed by reconstruction.

After a chip unit component formed by pre-bonding the first chip 410 and a first conductive bump 4011 on the redistribution layer 401 of the second chip component is aligned with the first substrate 450, the first chip 410 is fixed in a cavity, for example, a through hole, of the first substrate 450 by a bonding material 480. A first connecting surface 412 of the first chip 410 protrudes from, for example, a third connecting surface 451 of the first substrate 450. A first heat-conducting surface 411 of the first chip 410 is connected to a first heat conductor.

The size of the reconstructed second chip component is larger than that of the first chip 410. Two sides of the redistribution layer 401 of the second chip component protrude from edges on two sides of the first chip 410, respectively. The redistribution layer 401 protrudes toward the third connecting surface 451 of the first substrate 450 to form a plurality of second conductive bumps 4012, and the plurality of second conductive bumps 4012 is electrically connected to corresponding first bonding pads 454 on the third connecting surface 451. The second conductive bumps 4012 and the first bonding pads 454 are electrically connected by means of, but not limited to, tin-gold bonding.

In this embodiment, the second chip 420 is electrically connected to the first chip 410 and the first substrate 450 that are below the second chip 420 by the redistribution layer 401. For example, the first chip 410 is an HBM and the second chip 420 is a CPU.

In addition, the plastic package layer 402 may be filled with a material with a high heat conductivity, such that the plastic package layer 402 may be used as the second heat conductor on the second heat-conducting surface 421 of the second chip 420.

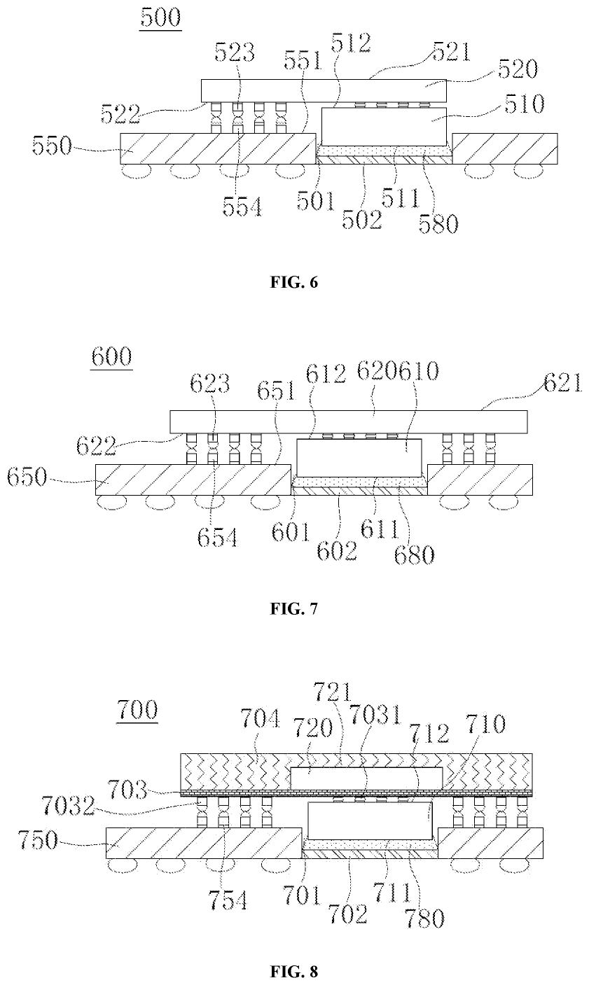

As shown in FIG. 6, a packaging structure 500 is further provided according to a fifth embodiment of the present invention, and differs from the packaging structure 100 in that 1) one side of a second chip 520 in the packaging structure 500 is electrically connected to a first substrate 550; 2) a cavity 501 in the first substrate 550 is for example a blind hole; and 3) a first heat-conducting surface 511 may conduct heat by a bottom 502 of the blind hole 501, wherein the bottom 502 is provided with a heat-conducting metal (copper coin), and the function of the heat-conducting metal (copper coin) may be regarded as similar to the function of the first heat conductor 30 in the packaging structure 100.

In addition, in order to simplify the diagram, illustrations of the first heat conductor, the second heat conductor and the second substrate are omitted in the packaging structure 500 shown in FIG. 6. A reference may be made to FIG. 1 for the first heat conductor, the second heat conductor and the second substrate, which are not repeated herein.

In this embodiment, after a chip unit component formed by pre-bonding a first chip 510 and the second chip 520 is aligned with the first substrate 550, the first chip 510 is fixed in a cavity 501, for example, a through hole, of the first substrate 550 by a bonding material 580. A gap between a first connecting surface 511 of the first chip 510 and the bottom 502 is filled with a heat-conducting bonding material 580. A first connecting surface 512 of the first chip 510 protrudes from, for example, a third connecting surface 551 of the first substrate 550. A second heat-conducting surface 520 of the second chip 520 is connected to a second heat conductor.

In this embodiment, the material of the bottom 502 contains more heat-conducting metals, for example, more provided exposed copper layers, than the material of other areas of the first substrate 550, such that the heat in the first chip 510 is dissipated after heat exchange with the outside as much as possible by the exposed copper layers. In addition, the outer side of the bottom 502 may also be connected to an extension of the first heat conductor 30 (as shown in FIG. 1) by a binding material.

The size of the second chip 520 is larger than that of the first chip 510. One side of the second chip 520 protrudes from an edge of the first chip 510. A part of the second connecting surface 522 of the second chip 520 faces a part of the third connecting surface 551 of the first substrate 550. Metal bumps 523 on the second connecting surface 522 are electrically connected to first bonding pads 554 on the third connecting surface 551. The metal bumps 523 and the first bonding pads 554 are electrically connected by means of, but not limited to, tin-gold bonding.

In this embodiment, the second chip 520 is electrically connected to the first chip 510 and the first substrate 550 that are below the second chip 520. For example, the first chip 510 is an HBM and the second chip 520 is a CPU.

As shown in FIG. 7, a packaging structure 600 is further provided according to a sixth embodiment of the present invention, and differs from the packaging structure 100 in that 1) two sides of a second chip 620 in the packaging structure 600 are electrically connected to a first substrate 650; 2) a cavity 601 in the first substrate 650 is for example a blind hole; and 3) a first heat-conducting surface 611 may conduct heat by a bottom 602 of the blind hole 601, wherein the bottom 602 is provided with a heat-conducting metal (cooper coin), and the function of the heat-conducting metal (cooper coin) may be regarded as similar to the function of the first heat conductor 30 in the packaging structure 100.

In addition, in order to simplify the diagram, illustrations of the first heat conductor, the second heat conductor and the second substrate are omitted in the packaging structure 600 shown in FIG. 7. A reference may be made to FIG. 1 for the first heat conductor, the second heat conductor and the second substrate, which are not repeated herein.

In this embodiment, after a chip unit component formed by pre-bonding a first chip 610 and the second chip 620 is aligned with the first substrate 650, the first chip 610 is fixed in a cavity 601, for example, a through hole, of the first substrate 650 by a bonding material 680. A gap between a first connecting surface 61 of the first chip 610 and the bottom 602 is filled with a bonding material 680. A first connecting surface 612 of the first chip 610 protrudes from, for example, a third connecting surface 651 of the first substrate 650. A second heat-conducting surface 621 of the second chip 620 is connected to a second heat conductor.

In this embodiment, the material of the bottom 602 contains more heat-conducting metals, for example, more exposed copper layers, than the material of other areas of the first substrate 650, such that the heat in the first chip 610 is dissipated after heat exchange with the outside as much as possible by the exposed copper layers. In addition, the outer side of the bottom 602 may also be connected to an extension of the first heat conductor 30 (as shown in FIG. 1) by a binding material.

The second chip 620 is larger than the first chip 610. Two sides of the second chip 620 protrude from edges on two sides of the first chip 610. A part of the second connecting surface 622 of the second chip 620 faces a part of the third connecting surface 651 of the first substrate 650. Metal bumps 623 on the second connecting surface 622 are electrically connected to first bonding pads 654 on the third connecting surface 651. The metal bumps 623 and the first bonding pads 654 are electrically connected by means of, but not limited to, tin-gold bonding.

In this embodiment, the second chip 620 is electrically connected to the first chip 610 and the first substrate 650 that are below the second chip 620. For example, the first chip 610 is an HBM, the second chip 620 is a CPU, and the HBM is powered up by the CPU.

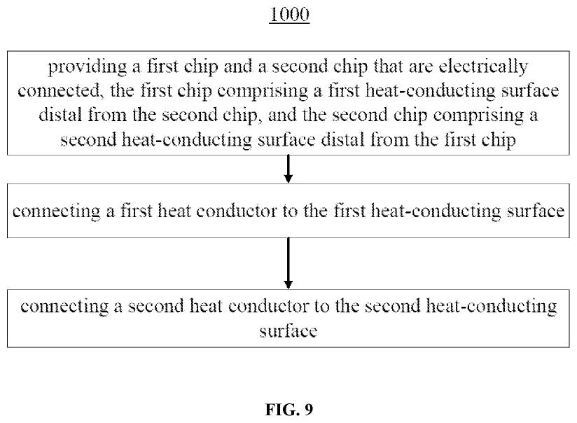

As shown in FIG. 8, a packaging structure 700 is further provided according to a seventh embodiment of the present invention, and differs from the packaging structure 100 in that 1) a second chip 720 in the packaging structure 700 is electrically connected to a first substrate 750 and a first chip 710 by a redistribution layer 703; 2) a cavity 701 in the first substrate 750 is for example a blind hole; and 3) a first heat-conducting surface 711 of the first chip 710 may conduct heat by a bottom 702 of the blind hole 701, wherein the bottom 702 is provided with a heat-conducting metal (cooper coin), and the function of the heat-conducting metal (cooper coin) may be regarded as similar to the function of the first heat conductor 30 in the packaging structure 100.

In addition, in order to simplify the diagram, illustrations of the first heat conductor, the second heat conductor and the second substrate are omitted in the packaging structure 700 shown in FIG. 8. A reference may be made to FIG. 1 for the first heat conductor, the second heat conductor and the second substrate, which are not repeated herein.

In this embodiment, the second chip 720 includes a plastic package layer 704 around the second chip 720; an active layer of the second chip 720 is exposed from the plastic package layer 704 and is approximately flush with the plastic package layer 704; the redistribution layer 703 is formed one side of the plastic package layer 704, and is electrically connected to the active layer; and thus, second chip component is formed by reconstruction.

After a chip unit component formed by pre-bonding the first chip 710 and a first conductive bump 7031 on the redistribution layer 703 of the second chip component is aligned with the first substrate 750, the first chip 710 is fixed in a cavity 701, for example, a blind hole, of the first substrate 750. A gap between a first heat-conducting surface 711 of the first chip 710 and a bottom 702 is filled with a bonding material 780. A first connecting surface 712 of the first chip 710 protrudes from, for example, a third connecting surface 751 of the first substrate 750. A first heat-conducting surface 711 of the first chip 710 is connected to a first heat conductor.

In this embodiment, the material of the bottom 702 contains more heat-conducting metals, for example, more exposed copper layers, than the material of other areas of the first substrate 750, such that the heat in the first chip 710 is dissipated after heat exchange with the outside as much as possible by the exposed copper layers. In addition, the outer side of the bottom 702 may also be connected to an extension of the first heat conductor 30 (as shown in FIG. 1) by a binding material.

The size of the reconstructed second chip component is larger than the size of the first chip 710. Two sides of the redistribution layer 703 of the second chip component protrude from edges on two sides of the first chip 710, respectively. The redistribution layer 703 protrudes toward the third connecting surface 751 of the first substrate 750 to form a plurality of second conductive bumps 7032, and the plurality of second conductive bumps 7032 is electrically connected to corresponding first bonding pads 754 on the third connecting surface 751. The second conductive bumps 7032 and the first bonding pads 754 are electrically connected by means of, but not limited to, tin-gold bonding.

In this embodiment, the second chip 720 is electrically connected to the first chip 710 and the first substrate 750 that are below the second chip 720 by the redistribution layer 703. For example, the first chip 710 is an HBM and the second chip 720 is a CPU.

In addition, the plastic package layer 704 may be filled with a material with high heat conductivity, such that the plastic package layer 704 may be used as the second heat conductor on the second heat-conducting surface 721 of the second chip 720.

As shown in FIG. 9, another object of the present invention is to provide a manufacturing method 1000 of a packaging structure, including:

providing a first chip and a second chip that are electrically connected, the first chip including a first heat-conducting surface distal from the second chip, and the second chip including a second heat-conducting surface distal from the first chip;

connecting a first heat conductor to the first heat-conducting surface; and

connecting a second heat conductor to the second heat-conducting surface.

In a preferred embodiment, prior to connecting the first heat conductor to the first heat-conducting surface, the manufacturing method further includes:

providing a first substrate having a cavity, the cavity being a through hole; placing the first chip into the through hole, and enabling the first heat-conducting surface to be exposed from the through hole; and filling a gap between the first chip and the cavity with a bonding material, and fixing the first chip to the first substrate.

In a preferred embodiment, connecting the first heat conductor to the first heat-conducting surface further includes:

providing a first substrate having a cavity, the cavity being a blind hole, the first heat conductor being disposed at a bottom of the blind hole; and placing the first chip into the blind hole, and connecting the first heat conductor to the first heat-conducting surface.

With reference to FIGS. 1, 2 and 9, the process of the above-mentioned manufacturing method 1000 will be explained in detail with the packaging structure 100.

The process includes: firstly, bonding a first chip 10 and a second chip 20, and causing a first heat-conducting surface 11 of the first chip 10 and a second heat-conducting surface 21 of the second chip 20 to face away from each other; secondly, providing a first substrate 50, and forming a cavity 52 in the first substrate 50; thirdly, placing the first chip 10 bonded to the second chip 20 into the cavity 52, and in the case that the cavity 52 is a through hole, exposing the first heat-conducting surface 11 from the through hole; then, filling a gap 53 between the first chip 10 and the cavity 52 with a bonding material 80, and fixing the first chip 10 in the cavity 52 of the first substrate 50; after that, bonding an interposer 70 to a first connecting surface 12 of the first chip 10 and a third connecting surface 51 of the first substrate 50; then, providing a second substrate 60, bonding the second substrate 60 below the first substrate 50, and causing a notch 61 of the second substrate 60 to be communicated with the cavity 52; afterwards, inserting an extension of a first heat conductor 30 into the notch 61 and enabling the extension to pass through the notch 61 to be connected to the first heat-conducting surface 11; and finally, connecting the second heat conductor 40 to the second heat-conducting surface 21.

The order of connecting the first heat conductor 30 to the second heat conductor 40 may be exchanged according to actual needs.

In addition, in other embodiments of the present invention, firstly, the first chip is placed into the cavity of the first substrate; secondly, the second chip is bonded above or below the first chip; and then sequentially, the first chip is fixed, the first substrate and the second substrate are bonded, and the first heat conductor and the second heat conductor are connected.

The present invention provides the packaging structure and the manufacturing method thereof. The packaging structure includes the first chip and the second chip that are electrically connected. The first chip includes the first heat-conducting surface distal from the second chip, and the second chip includes the second heat-conducting surface distal from the first chip. The first heat conductor and the second heat conductor are respectively disposed on the first heat-conducting surface and the second heat-conducting surface which are away from each other to lead out heat produced by operations of the first chip and the second chip. That is, a first heat-conducting channel is formed between the first heat-conducting surface of the first chip and the first heat conductor, and a second heat-conducting channel is formed between the second heat-conducting surface of the second chip and the second heat conductor. The first heat-conducting channel and the second heat-conducting channel accelerate heat conduction, and thus, the heat dissipation efficiency of the packaging structure can be significantly improved.

The present invention has been described by the above-mentioned related embodiments which, however, are only examples for implementing the present invention. In addition, the technical features involved in the different embodiments of the present invention described above can be combined with each other as long as they do not conflict with each other. It is necessary to point out that there may be many other embodiments, and those skilled in the art can make various corresponding changes and modifications according to the present invention without departing from the spirit and essence of the present invention, but these corresponding changes and modifications should all fall within the scope of protection of the appended claims.

What is claimed is:

1. A packaging structure, comprising:
a first chip, comprising a first connecting surface and a first heat-conducting surface that face away from each other;
a second chip, disposed on a side of the first connecting surface and electrically connected to the first chip, wherein a side of the second chip distal from the first chip comprises a second heat-conducting surface; and
a first heat conductor and a second heat conductor, the first heat conductor being connected to the first heat-conducting surface, and the second heat conductor being connected to the second heat-conducting surface.

2. The packaging structure according to claim 1, further comprising a first substrate having a cavity in which the first chip is placed, wherein a gap between the first chip and the cavity is filled with a bonding material.

3. The packaging structure according to claim 2, wherein the cavity is a through hole running through the first substrate, and the first heat-conducting surface is exposed from the through hole.

4. The packaging structure according to claim 3, wherein the first heat conductor is disposed on a side of the first substrate distal from the second chip, and connected to the first heat-conducting surface exposed from the through hole.

5. The packaging structure according to claim 4, further comprising:
a second substrate, disposed on a side of the first substrate distal from the second chip and electrically connected to the first substrate; and
the first heat conductor comprises a heat-conducting back plate and an extension extending from the heat-conducting back plate;
wherein the second substrate is provided with a notch for the extension, the extension is inserted into the notch to be connected to the first heat-conducting surface, and the second substrate is sandwiched between the first substrate and the heat-conducting back plate.

6. The packaging structure according to claim 2, wherein the cavity is a blind hole not running through the first substrate, and the first heat-conducting surface is connected to a bottom of the blind hole.

7. The packaging structure according to claim 6, wherein the first heat conductor is disposed on an outer side of the bottom of the blind hole and connected to the bottom of the blind hole.

8. The packaging structure according to claim 2, wherein a size of the second chip is larger than a size of the first chip, and a metal bump protrudes from a second connecting surface of the second chip facing the first substrate and is electrically connected to a corresponding first bonding pad on the first substrate.

9. The packaging structure according to claim 2, further comprising an interposer, wherein the interposer is electrically connected to the first chip and the first substrate.

10. The packaging structure according to claim 9, wherein a part of a heat-conducting area of the second heat conductor covers a side of the interposer distal from the first substrate.

11. The packaging structure according to claim 2, wherein a side of the second chip facing the first chip comprises an interconnecting structural layer, and the interconnecting structural layer is electrically connected to the first chip and the first substrate.

12. The packaging structure according to claim 2, wherein the first chip further comprises a first connecting surface facing away from the first heat-conducting surface, and the first connecting surface protrudes from or is flush with a third connecting surface of the first substrate.

13. A manufacturing method of a packaging structure, comprising:
providing a first chip and a second chip that are electrically connected, the first chip comprising a first heat-conducting surface distal from the second chip, and the second chip comprising a second heat-conducting surface distal from the first chip;
connecting a first heat conductor to the first heat-conducting surface; and
connecting a second heat conductor to the second heat-conducting surface.

14. The manufacturing method according to claim 13, wherein prior to connecting the first heat conductor to the first heat-conducting surface, the manufacturing method further comprises:
providing a first substrate having a cavity, the cavity being a through hole;
placing the first chip into the through hole, and exposing the first heat-conducting surface from the through hole; and
filling a gap between the first chip and the cavity with a bonding material, and fixing the first chip to the first substrate.

15. The manufacturing method according to claim 13, wherein connecting the first heat conductor to the first heat-conducting surface further comprises:
providing a first substrate having a cavity, the cavity being a blind hole, and the first heat conductor being disposed at a bottom of the blind hole; and
placing the first chip into the blind hole, and connecting the first heat conductor to the first heat-conducting surface.
